(19) United States
(12) Patent Application Publication
(10) Pub. No.: US 2026/0163457 A1
(43) Pub. Date: Jun. 11, 2026

(54) ELECTRIC WORK MACHINE, AND METHOD FOR CONSTRUCTING ELECTRICAL SYSTEM IN ELECTRIC WORK MACHINE

(71) Applicant: MAKITA CORPORATION, Anjo-shi (JP)

(72) Inventors: Katsuna HAYASHI, Anjo-shi (JP); Kisho Sekido, Anjo-shi (JP); Takeshi Yokoi, Anjo-shi (JP); Sora Hibino, Anjo-shi (JP)

(73) Assignee: MAKITA CORPORATION, Anjo-shi (JP)

(21) Appl. No.: 19/409,058

(22) Filed: Dec. 4, 2025

(30) Foreign Application Priority Data
Dec. 6, 2024 (JP) 2024-213774

(51) Int. Cl. H02K 11/33; B25F 5/00; H02K 7/14; H10D 80/20; H10W 40/22; H10W 40/50; H10W 40/60; H10W 90/15; H10W 90/22

(52) U.S. Cl. CPC H02K 11/33; H02K 7/145; H10D 80/251; H10W 40/228; H10W 40/50; H10W 40/611; H10W 90/15; H10W 90/22; B25F 5/008; H02K 2211/03

(57) ABSTRACT

One aspect of the present disclosure provides an electric work machine including a motor, a drive circuit, and a semiconductor load switch. The drive circuit includes a first semiconductor switch having a surface-mount package. The semiconductor load switch has a through-hole package and is configured to establish or interrupt conduction between the drive circuit and a power supply for the motor.

### CROSS-REFERENCE TO RELATED APPLICATIONS

This application claims the benefit of Japanese Patent Application No. 2024-213774 filed on Dec. 6, 2024 with the Japan Patent Office, the entire disclosure of which is incorporated herein by reference.

### BACKGROUND

The present disclosure relates to an electric work machine.

Japanese Patent No. 7536631 discloses an electric work machine that includes a motor and a circuit board.

In this electric work machine, six FET chips are mounted on the circuit board by surface mounting. These FET chips form a drive circuit for the motor. An electric current flowing through the motor is controlled by switching operation of these FET chips.

Further, an additional FET chip for completing or interrupting a power line is mounted on the circuit board by surface mounting. The power line couples the drive circuit to a positive electrode of a battery.

### SUMMARY

In the above-described electric work machine, when any fault occurs in the electric work machine, the additional FET chip is turned off to interrupt the power line. As a result, the electric current flowing through the motor is forcibly interrupted, and the motor is forcibly stopped. For the safety of a user, it is desirable that the power line can be interrupted with high reliability.

Accordingly, it is desirable that one aspect of the present disclosure can provide a technique capable of decoupling a drive circuit from a power supply for a motor with high reliability, in an electric work machine.

One aspect of the present disclosure provides an electric work machine including a motor, a drive circuit, and a semiconductor load switch.

The drive circuit (i) includes a first semiconductor switch having a surface-mount package and (ii) is configured to control a motor current by switching operation of the first semiconductor switch. The motor current flows or is to flow between the drive circuit and the motor for driving the motor.

The semiconductor load switch has a through-hole package and is configured to establish or interrupt conduction between the drive circuit and a power supply for the motor.

In general, a semiconductor switch having a through-hole package may have a rated voltage and a rated current greater than those of a semiconductor switch having a surface-mount package.

Thus, the semiconductor load switch is less prone to failure even in a situation where, for example, failure (e.g., short-circuit breakdown) occurs in the first semiconductor switch, and can decouple the drive circuit from the power supply with high reliability.

Accordingly, the electric work machine makes it possible to achieve a high level of safety by means of the semiconductor load switch having the through-hole package.

Another aspect of the present disclosure provides a method for constructing an electrical system in an electric work machine, the method including:
providing a semiconductor switch having a surface-mount package to a drive circuit of the electric work machine, the drive circuit being configured to control a motor current flowing or to flow through a motor of the electric work machine by switching operation of the semiconductor switch; and,
coupling the drive circuit to a power supply for the motor via a semiconductor load switch having a through-hole package, the semiconductor load switch being configured to establish or interrupt conduction between the drive circuit and the power supply.

According to such a method, the drive circuit can be decoupled from the power supply with high reliability by means of the semiconductor load switch having the through-hole package.

### BRIEF DESCRIPTION OF THE DRAWINGS

Example embodiments of the present disclosure will be described hereinafter with reference to the accompanying drawings, in which:

FIG. 1 is a view showing an external appearance of an electric work machine according to first and second embodiments;

FIG. 2 is a diagram showing an electrical configuration of the electric work machine according to the first and second embodiments;

FIG. 3 is a plan view showing a circuit board on which a drive circuit according to the first embodiment is mounted;

FIG. 4 shows a longitudinal cross-sectional view of the circuit board according to the first embodiment;

FIG. 5 shows a longitudinal cross-sectional view, in a modified example, of the circuit board according to the first embodiment;

FIG. 6 is a view showing a first circuit surface of a circuit board on which a drive circuit according to the second embodiment is mounted;

FIG. 7 is a view showing a second circuit surface of the circuit board according to the second embodiment;

FIG. 8 is a view showing an external appearance of a metal component to be inserted into the circuit board according to the second embodiment;

FIG. 9 is a view showing electrical coupling between a source terminal of a first semiconductor switch and a drain terminal of a fourth semiconductor switch, according to the second embodiment;

FIG. 10 is a view showing a longitudinal cross-section of the circuit board according to the second embodiment;

FIG. 11 is a perspective view showing an external appearance of a heat dissipation member according to the first and second embodiments;

FIG. 12 is a perspective view showing an external appearance of a heat dissipation member according to another embodiment;

FIG. 13 is a view showing an electrical configuration of an electric work machine according to another embodiment; and

FIGS. 14A and 14B are partial longitudinal cross-sectional views of drive units according to other embodiments.

### DETAILED DESCRIPTION OF EXEMPLARY EMBODIMENTS

### Overview of Embodiments

In the present disclosure, ordinal numbers such as “first” and “second” are merely intended to distinguish the elements from each other, and are not intended to limit the order and/or number of the elements. Thus, the first element may be referred to as the second element, and similarly, the second element may be referred to as the first element. In addition, the first element may be provided without the second element, and similarly, the second element may be provided without the first element.

One embodiment may provide an electric work machine (or an electric power tool, or a motor-operated appliance, or a motor-driven appliance, or a job-site device, or an outdoor power equipment (OPE)) including at least any one of:
Feature 1: a motor configured to drive a tool;
Feature 2: a drive circuit (i) including a first semiconductor switch having a surface-mount package (or packaged as a surface-mount device, or in a surface-mount package) and (ii) configured to control a motor current (or a drive current) by switching operation of the first semiconductor switch;
Feature 3: the motor current flows or is to flow between the drive circuit and the motor for driving the motor; and
Feature 4: a semiconductor load switch (i) having a through-hole package (or packaged as a through-hole device, or in a through-hole package) and (ii) configured to establish or interrupt conduction between the drive circuit and a power supply for the motor.

The electric work machine including at least Features 1 through 4 makes it possible not only to achieve a reduction in the size of the drive circuit by means of the first semiconductor switch having the surface-mount package, but also to decouple the drive circuit from the power supply with high reliability by means of the semiconductor load switch having the through-hole package.

The first semiconductor switch may generate significant heat due to the switching operation for controlling the motor current (and further, due to the resulting switching loss). The semiconductor load switch is turned on or off not to control the motor current but to establish or interrupt conduction between the drive circuit and the power supply. That is, the semiconductor load switch does not perform a frequent switching operation as performed by the first semiconductor switch (i.e., less frequent switching is performed). More specifically, the semiconductor load switch is kept on (i.e., not turned off) while the electric work machine is operating properly (or as long as the electric work machine operates properly). Thus, the switching loss of the semiconductor load switch is small, and generation of significant heat from the semiconductor load switch is inhibited. As a result, failure of the semiconductor load switch caused by the generated heat is less likely to occur. This allows the semiconductor load switch to properly interrupt the motor current upon a fault in the electric work machine, which can enhance the safety of the electric work machine.

The semiconductor load switch may be configured to interrupt conduction between the drive circuit and the power supply for the motor (or to decouple the drive circuit from the power supply for the motor) in response to occurrence of a pre-designated event. Examples of the pre-designated event include, but are not limited to, any fault of the electric work machine, such as a short-circuit fault in the electric work machine.

The tool may be any tool. Examples of the tool include, but are not limited to, a tool bit, a saw chain, a saw blade, a mowing blade, a nylon cutter, a grinding wheel, a grinding disc, a buffing wheel, a polishing wheel, a needle, a nail, a pump, a wheel, and a fan blade (or an impeller).

One embodiment may include, in addition to or in place of at least any one of Features 1 through 4, at least any one of:
Feature 5: a circuit board including a via passing through the circuit board along a thickness thereof;
Feature 6: the semiconductor load switch includes a body;
Feature 7: the semiconductor load switch includes a lead protruding from the body; and
Feature 8: the semiconductor load switch is mounted on the circuit board with the lead inserted into the via.

In the electric work machine including at least Features 1 through 8, the lead of the semiconductor load switch is inserted into the via of the circuit board, and thus, the semiconductor load switch can exhibit high resistance to impact shock, high resistance to vibration, and/or high resistance to environmental conditions. Accordingly, the semiconductor load switch can decouple the drive circuit from the power supply with high reliability in applications where the electric work machine is prone to impact shock and/or vibration or under severe environments as well.

One embodiment may include, in addition to or in place of at least any one of Features 1 through 8,
Feature 9: the semiconductor load switch is of a radial lead type.

In the electric work machine including at least Features 1 through 9, it is easy to insert the lead into the via, resulting in allowing the semiconductor load switch to be easily mounted on the circuit board.

One embodiment may include, in addition to or in place of at least any one of Features 1 through 9,
Feature 10: the body of the semiconductor load switch is spaced apart from the circuit board.

In the electric work machine including at least Features 1 through 10, the circuit board can be inhibited from being heated by heat generated in the body of the semiconductor load switch.

One embodiment may include, in addition to or in place of at least any one of Features 1 through 10,
Feature 11: the first semiconductor switch is mounted on the circuit board by surface mounting.

In the electric work machine including at least Features 1 through 8 and 11, the first semiconductor switch is disposed on the circuit board together with the semiconductor load switch, thus allowing the electric work machine to be reduced in size. In addition, the body of the semiconductor load switch can be inhibited from being heated by the first semiconductor switch through the circuit board since the body of the semiconductor load switch is spaced apart from the circuit board.

One embodiment may include, in addition to or in place of at least any one of Features 1 through 11, at least any one of:
Feature 12: the drive circuit includes a second semiconductor switch having a surface-mount package (or packaged as a surface-mount device, or in a surface-mount package);
Feature 13: the second semiconductor switch is distinct from the first semiconductor switch;
Feature 14: the second semiconductor switch is mounted on the circuit board by surface mounting; and
Feature 15: the second semiconductor switch forms, together with the first semiconductor switch, at least a part of an inverter circuit for driving the motor.

In the electric work machine including at least Features 1 through 8 and 11 through 15, the motor can be driven by the inverter circuit. In addition, since the second semiconductor switch is disposed on the circuit board together with the first semiconductor switch and the semiconductor load switch, the electric work machine can be reduced in size.

One embodiment may include, in addition to or in place of at least any one of Features 1 through 15,
Feature 16: a heat dissipation member (i) in direct or indirect contact with the first semiconductor switch and with the body of the semiconductor load switch and (ii) configured to dissipate heat generated in the first semiconductor switch and heat generated in the semiconductor load switch.

In the electric work machine including at least Features 1 through 8, 11, and 16, thermal runaway of the first semiconductor switch and the semiconductor load switch can be inhibited. In addition, since the heat dissipation member is shared by the first semiconductor switch and the semiconductor load switch, an increase in the number of components of the electric work machine can be inhibited.

One embodiment may include, in addition to or in place of at least any one of Features 1 through 16, at least any one of:
Feature 17: the heat dissipation member includes a first contact surface in direct or indirect contact with the first semiconductor switch; and
Feature 18: the heat dissipation member includes a second contact surface in direct or indirect contact with the body of the semiconductor load switch.

In the electric work machine including at least Features 1 through 8, 11, and 16 through 18, the heat dissipation member can establish respective thermal conduction paths separately for the first semiconductor switch and the semiconductor load switch, thus allowing the corresponding heats to be dissipated smoothly.

One embodiment may include, in addition to or in place of at least any one of Features 1 through 18,
Feature 19: the first contact surface is in direct or indirect contact with the second semiconductor switch in addition to the first semiconductor switch.

In the electric work machine including at least Features 1 through 8, 11, and 16 through 19, the heat dissipation member can dissipate heat generated in the second semiconductor switch in addition to heat generated in the first semiconductor switch and heat generated in the semiconductor load switch.

One embodiment may include, in addition to or in place of at least any one of Features 1 through 19,
Feature 20: the first contact surface is distinct from the second contact surface.

In the electric work machine including at least Features 1 through 8, 11, and 16 through 20, the first contact surface and the second contact surface of the heat dissipation member can each be made smaller than in a case where the first contact surface and the second contact surface are coplanar. As a result, an increase in the size of the electric work machine can be inhibited.

One embodiment may include, in addition to or in place of at least any one of Features 1 through 20, at least any one of:
Feature 21: the second contact surface extends in a direction intersecting the first contact surface; and
Feature 22: the second contact surface extends perpendicularly to the first contact surface.

In the electric work machine including at least Features 1 through 8, 11 through 16, 20, and 21, or including at least Features 1 through 8, 11 through 16, and 20 through 22, the location of the first semiconductor switch on the heat dissipation member can be inhibited from overlapping with the location of the semiconductor load switch on the heat dissipation member. As a result, the respective thermal conduction paths of the first semiconductor switch and the semiconductor load switch can be established while inhibiting interference therebetween.

One embodiment may include, in addition to or in place of at least any one of Features 1 through 22, at least any one of:
Feature 23: the heat dissipation member includes two or more fins; and
Feature 24: the heat dissipation member includes an attachment portion including the second contact surface.

In the electric work machine including at least Features 1 through 8, 11, 16 through 18, 22, and 24, the two or more fins can ensure as large a heat dissipation area as possible without an increase in the size of the electric work machine.

One embodiment may include, in addition to or in place of at least any one of Features 1 through 24, at least any one of:
Feature 25: the two or more fins are plate-shaped members parallel to each other;
Feature 26: the attachment portion is a plate-shaped member having a thickness greater than that of any of the two or more fins; and
Feature 27: the attachment portion is a plate-shaped member parallel to the two or more fins.

In the electric work machine including at least Features 1 through 8, 11, 16 through 18, and 23 through 27, two or more airflows can pass between adjacent two of the two or more fins and between one of the two or more fins and the attachment portion, thus enhancing the heat dissipation capacity of the heat dissipation member. In addition, the attachment portion can stably support the semiconductor load switch by its thickness.

One embodiment may include, in addition to or in place of at least any one of Features 1 through 27,
Feature 28: a heat dissipation member (i) in direct or indirect contact with the first semiconductor switch, with the second semiconductor switch, and with the body of the semiconductor load switch and (ii) configured to dissipate heat generated in the first semiconductor switch, heat generated in the second semiconductor switch, and heat generated in the semiconductor load switch.

In the electric work machine including at least Features 1 through 8, 11, and 28, thermal runaway of the first semiconductor switch, the second semiconductor switch, and the semiconductor load switch can be inhibited. In addition, since the heat dissipation member is shared by the first semiconductor switch, the second semiconductor switch, and the semiconductor load switch, an increase in the number of components of the electric work machine can be inhibited.

One embodiment may include, in addition to or in place of at least any one of Features 1 through 28,
Feature 29: the motor is a brushless DC motor.

Alternatively, the motor may be a brushed motor, an AC motor, or a stepper motor.

One embodiment may include, in addition to or in place of at least any one of Features 1 through 29, at least any one of:
Feature 30: a power line configured to deliver (or carry) the motor current from a positive electrode of the power supply to the drive circuit;
Feature 31: a ground line configured to deliver (or carry) the motor current from the drive circuit to a negative electrode of the power supply; and
Feature 32: the semiconductor load switch is on the power line or on the ground line.

In the electric work machine including at least Features 1 through 4 and 30 through 32, the power line or the ground line can be interrupted by the semiconductor load switch with high reliability.

Examples of the surface-mount package include, but are not limited to, a top-side cooling package and a dual-side cooling package (or a double-sided cooling package).

Examples of the top-side cooling package include, but are not limited to, TO-Leaded Top-side cooling (TOLT) package. Examples of the dual-side cooling package include, but are not limited to, Double-side-cooling Small Outline Package (DSOP). Examples of the first semiconductor switch and the second semiconductor switch include, but are not limited to, a metal-oxide-semiconductor field-effect transistor (MOSFET), a junction field-effect transistor (JFET), an insulated-gate bipolar transistor (IGBT), a bipolar transistor, a solid-state relay (SSR), and a thyristor.

Examples of the electric work machine include, but are not limited to, various electric apparatuses used in job sites of do-it-yourself carpentry, manufacturing, horticulture, gardening, construction, and so on, specifically, electric power tools for masonry work, metalworking, and woodworking, work machines for gardening, and devices for creating an environment of job sites, and more specifically, electric blowers, electric hammers, electric hammer drills, electric drills, electric drivers, electric wrenches, electric grinders, electric polishers, electric circular saws, electric reciprocating saws, electric jig saws, electric cutters, electric chain saws, electric planes, electric nailing machines (including electric tackers), electric hedge trimmers, electric lawn mowers, electric lawn trimmers, electric bush/grass cutters, electric cleaners, electric sprayers, electric spreaders, electric dust collectors (or electric dust extractors), electric bicycles (or e-bikes), and battery-powered wheel barrows (or battery-powered dollies).

One embodiment may provide a method including at least any one of:
Feature 33: providing, to a drive circuit of an electric work machine, a semiconductor switch having a surface-mount package;
Feature 34: the drive circuit is configured to control a motor current flowing or to flow through a motor of the electric work machine by switching operation of the semiconductor switch;
Feature 35: coupling (or connecting) the drive circuit to a power supply for the motor via a semiconductor load switch having a through-hole package; and
Feature 36: the semiconductor load switch is configured to establish or interrupt conduction between the drive circuit and the power supply.

According to the method including at least Features 33 through 36, it is possible not only to achieve a reduction in the size of the drive circuit by means of the semiconductor switch having the surface-mount package, but also to decouple the drive circuit from the power supply with high reliability by means of the semiconductor load switch having the through-hole package.

In one embodiment, Features 1 through 36 may be combined in any combination.

In one embodiment, any of Features 1 through 36 may be excluded.

### Specific Example Embodiments

Specific example embodiments will be described below. These specific example embodiments provide an electric work machine 1 in the form of an electric chain saw. The electric chain saw is a kind of gardening tool. However, the electric work machine 1 of this kind is merely an example, and the present disclosure can be applied to electric work machines in any forms.

### 1. First Embodiment

### 1-1. Configuration of Electric Work Machine

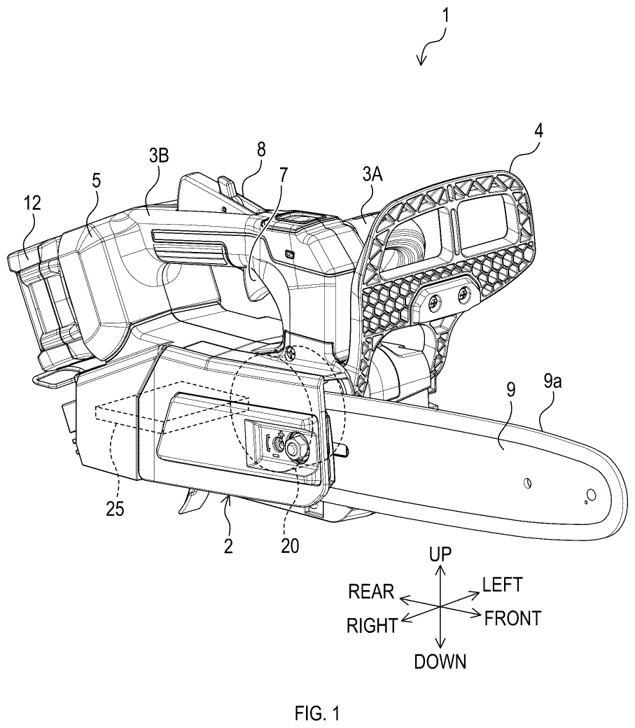

As shown in FIG. 1, the electric work machine 1 includes a housing 2. The housing 2 is made of synthetic resin. The housing 2 houses a motor 20. The housing 2 also houses a drive unit 25. The drive unit 25 includes: a circuit board 11; and a drive circuit 21 mounted on the circuit board 11, which will both be described below.

The words “upper”, “lower”, “front”, “rear”, “left”, and “right” in the descriptions below are used merely to facilitate easy understanding of the structures of the electric work machine 1 and its components, and are not intended to limit the orientations of the electric work machine 1 and its components. The electric work machine 1 and its components may be arranged in any orientation.

The electric work machine 1 includes a guide bar 9. The guide bar 9 is a plate-shaped member. The guide bar 9 protrudes from the housing 2 in a forward direction of the electric work machine 1.

The electric work machine 1 includes a saw chain 9a as a tool. The saw chain 9a includes multiple cutters connected to each other. The saw chain 9a is detachably attached to a peripheral edge of the guide bar 9. The saw chain 9a is coupled to a rotor shaft (not shown) of the motor 20 via a power transmission mechanism (not shown). The power transmission mechanism includes a sprocket (not shown) configured to receive the saw chain 9a thereon.

Thus, driving the motor 20 causes the saw chain 9a to move along the peripheral edge of the guide bar 9. Such movement of the saw chain 9a enables the electric work machine 1 to cut a workpiece.

The electric work machine 1 includes a battery attachment portion 5. The battery attachment portion 5 of the present embodiment protrudes upward from a rear part of the housing 2. The battery attachment portion 5 is where a battery pack 12 is detachably attached. The battery pack 12 is attachable to a rear end face of the battery attachment portion 5. The battery pack 12 includes a rechargeable battery. In the present embodiment, the rechargeable battery is a lithium-ion battery, but is not limited thereto. By being attached to the battery attachment portion 5, the battery pack 12 can supply DC power to the electric work machine 1.

In another embodiment, the electric work machine 1 may include a power cord in place of the battery attachment portion 5. The electric work machine 1 may receive AC power from an AC power supply, such as utility power (or AC mains), via the power cord. The AC power received from the AC power supply may be converted into DC power or into AC power with different characteristics in the electric work machine 1.

The electric work machine 1 includes a hand guard 4. The hand guard 4 protrudes upward from a front part of the housing 2.

The electric work machine 1 includes a side handle 3A and a top handle 3B positioned rearward of the hand guard 4. Either the side handle 3A or the top handle 3B may be omitted. The side handle 3A and the top handle 3B are made of synthetic resin.

The side handle 3A is a tubular member. The side handle 3A protrudes leftward from a left part of the housing 2. Thus, a user of the electric work machine 1 can grip the side handle 3A with the user's left hand from the rear of the electric work machine 1.

The top handle 3B protrudes upward from an upper part of the housing 2. A rear end of the top handle 3B is coupled to the battery attachment portion 5, thus forming a space between the top handle 3B and the housing 2. This enables the user to grip the top handle 3B by inserting the user's fingers through this space.

The electric work machine 1 includes a trigger switch 7 on the lower portion the top handle 3B. The trigger switch 7 is configured to be operated (e.g., pulled) by the user to drive the motor 20. Pulling the trigger switch 7 upward by the user causes the motor 20 to be driven. Upon releasing the operation of the trigger switch 7, driving of the motor 20 is stopped.

The electric work machine 1 includes a trigger lock lever 8 on the upper portion of the top handle 3B. The user presses the trigger lock lever 8 downward to releases the lock on the trigger switch 7.

### 1-2. Control Unit

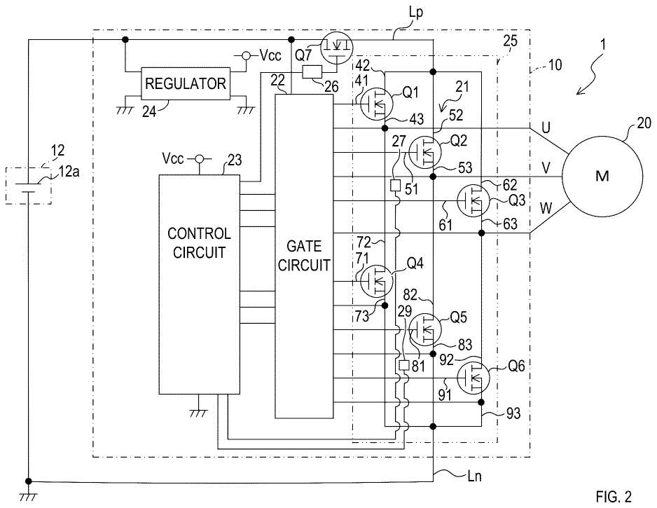

As shown in FIG. 2, the electric work machine 1 includes a control unit 10. The control unit 10 receives the DC power from a battery 12a within the battery pack 12 and controls the motor 20 so as to drive or stop the saw chain 9a. In the present embodiment, the motor 20 is a three-phase brushless DC motor. In another embodiment, the motor 20 may be a single-phase brushless DC motor, a two-phase brushless DC motor, a brushless DC motor with four or more phases, a brushed motor, an AC motor, or a stepper motor.

The control unit 10 includes: the drive unit 25 including a drive circuit 21; a gate circuit 22; a control circuit 23; and a regulator 24.

The drive circuit 21 is configured (i) to receive a DC motor current from the battery 12a, (ii) to convert the received DC motor current into three-phase AC motor currents (i.e., U-phase, V-phase, and W-phase motor currents), and (iii) to supply the three-phase AC motor currents to the three-phase windings of the motor 20. Specifically, the drive circuit 21 is a three-phase full-bridge inverter circuit including first through sixth semiconductor switches Q1 through Q6. In another embodiment, the drive circuit 21 may be a full-bridge inverter circuit with a single phase, two phases, or four or more phases, or may be a half-bridge inverter circuit.

Specifically, the first through sixth semiconductor switches Q1 through Q6 are FETs. More specifically, the first through sixth semiconductor switches Q1 through Q6 are N-channel MOSFETs. In another embodiment, at least one of the first through sixth semiconductor switches Q1 through Q6 may be a P-channel MOSFET, a JFET, an IGBT, a bipolar transistor, an SSR, or a thyristor.

In the drive circuit 21, the first through third semiconductor switches Q1 through Q3 are high-side switches. The first through third semiconductor switches Q1 through Q3 are respectively coupled to terminals U, V, and W of the motor 20 and to a power line Lp. The power line Lp is coupled to a positive electrode of the battery 12a. In the drive circuit 21, the fourth through sixth semiconductor switches Q4 through Q6 are low-side switches. The fourth through sixth semiconductor switches Q4 through Q6 are respectively coupled to the terminals U, V, and W of the motor 20 and to a ground line Ln. The ground line Ln is coupled to a negative electrode of the battery 12a.

The first through sixth semiconductor switches Q1 through Q6 include gate terminals 41, 51, 61, 71, 81, and 91; drain terminals 42, 52, 62, 72, 82, and 92; and source terminals 43, 53, 63, 73, 83, and 93, respectively. The gate terminals 41, 51, 61, 71, 81, and 91 of the first through sixth semiconductor switches Q1 through Q6 are coupled to the gate circuit 22. The drain terminals 42, 52, and 62 of the first through third semiconductor switches Q1 through Q3 are coupled to the power line Lp. The source terminals 73, 83, and 93 of the fourth through sixth semiconductor switches Q4 through Q6 are coupled to the ground line Ln. The source terminal 43 of the first semiconductor switch Q1 is coupled to the drain terminal 72 of the fourth semiconductor switch Q4 and to a U-phase of the motor 20. The source terminal 53 of the second semiconductor switch Q2 is coupled to the drain terminal 82 of the fifth semiconductor switch Q5 and to a V-phase of the motor 20. The source terminal 63 of the third semiconductor switch Q3 is coupled to the drain terminal 92 of the sixth semiconductor switch Q6 and to a W-phase of the motor 20.

The gate circuit 22 turns on or off the first through sixth semiconductor switches Q1 through Q6 in accordance with control signals supplied from the control circuit 23 to supply the three-phase AC motor currents to the three-phase windings of the motor 20. This results in rotating the motor 20.

The control circuit 23 includes a not-shown microcomputer (or microcontroller, or microprocessor). In another embodiment, the control circuit 23 may include an additional microcomputer. In still another embodiment, the control circuit 23 may include, in place of or in addition to the microcomputer, a graphics processing unit (GPU), a hardwired logic, an application specific integrated circuit (ASIC), an application specific standard product (ASSP), a programmable logic device (PLD) (e.g., a field programmable gate array (FPGA)), a discrete electronic component, and/or a combination thereof.

The regulator 24 is configured (i) to receive the DC power from the battery 12a and (ii) to generate a power-supply voltage Vcc. The power-supply voltage Vcc is supplied to internal circuits of the control unit 10, including the control circuit 23.

The control unit 10 further includes a load switch Q7 and a bootstrap 26. The load switch Q7 is disposed between the battery 12a and the drive circuit 21 on the power line Lp in order to protect the drive circuit 21 and/or the motor 20. The load switch Q7 is a semiconductor switch. Specifically, the load switch Q7 is an N-channel MOSFET. In another embodiment, the load switch Q7 may be a P-channel MOSFET, a JFET, an IGBT, a bipolar transistor, or an SSR. In still another embodiment, the load switch Q7 may be a mechanical relay. A gate terminal of the load switch Q7 is coupled to the control circuit 23 via the bootstrap 26. The load switch Q7 is maintained to be ON while driving of the motor 20 is permitted. The motor current flowing through the load switch Q7 can be larger than the motor current flowing through each of the first through sixth semiconductor switches Q1 through Q6. The voltage applied to the load switch Q7 can be larger than the voltage applied to each of the first through sixth semiconductor switches Q1 through Q6. Thus, the rated voltage and the rated current of the load switch Q7 are higher than those of the first through sixth semiconductor switches Q1 through Q6.

The drive circuit 21 includes first and second thermistors 27 and 29. The first thermistor 27 is disposed in the vicinity of the first through third semiconductor switches Q1 through Q3 to measure the temperature near the first through third semiconductor switches Q1 through Q3. The first thermistor 27 supplies, to the control circuit 23, a temperature detection signal indicating the measured temperature. The second thermistor 29 is disposed in the vicinity of the fourth through sixth semiconductor switches Q4 through Q6 to measure the temperature near the fourth through sixth semiconductor switches Q4 through Q6. The second thermistor 29 supplies, to the control circuit 23, a temperature detection signal indicating the measured temperature.

### 1-3. Drive Unit

### <1-3-1. Examples>

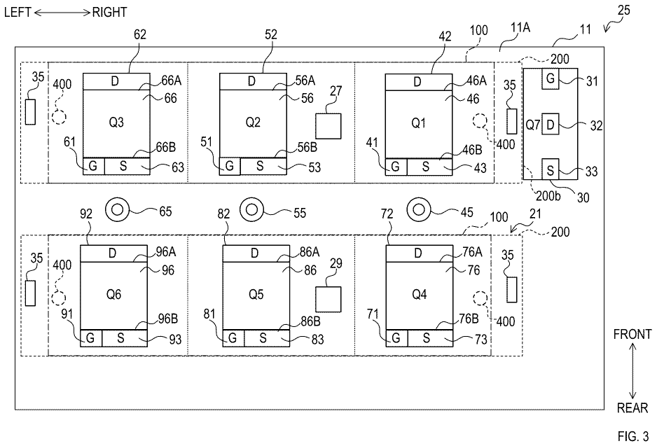

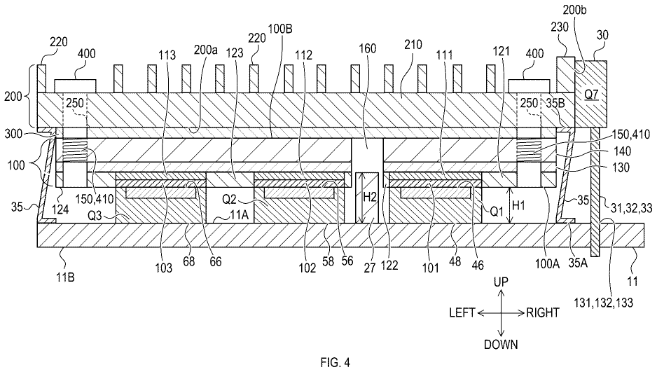

The drive unit 25 will be described with reference to FIGS. 3 and 4. The drive unit 25 includes: the circuit board 11; the drive circuit 21 mounted on the circuit board 11; four elastic members 35; two metal plates 100; two heat dissipation members 200; and four male screws 400. FIG. 3 shows the two metal plates 100, the two heat dissipation members 200, and the four male screws 400 in a transparent manner. In practice, the drive circuit 21 on the circuit board 11 is covered by the two metal plates 100 and the two heat dissipation members 200.

The circuit board 11 is a printed circuit board (PCB). The circuit board 11 has a rectangular planar shape. In another embodiment, the circuit board 11 may have a planar shape not rectangular. The circuit board 11 includes a first circuit surface 11A and a second circuit surface 11B. The second circuit surface 11B is disposed opposite the first circuit surface 11A.

The drive circuit 21 includes the first through sixth semiconductor switches Q1 through Q6, the first and second thermistors 27 and 29, the U-phase terminal 45, the V-phase terminal 55, and the W-phase terminal 65.

The first through sixth semiconductor switches Q1 through Q6 are of a surface-mount type. In other words, the first through sixth semiconductor switches Q1 through Q6 each have a surface-mount package. Specifically, the first through sixth semiconductor switches Q1 through Q6 each have a top-side cooled package, more specifically, a TOLT package. The first through sixth semiconductor switches Q1 through Q6 are of the same model, but are not limited to being of the same model. The first through sixth semiconductor switches Q1 through Q6 are disposed on the first circuit surface 11A. The first through third semiconductor switches Q1 through Q3 are arranged in a row along a longitudinal direction (left-right) on the front side of the first circuit surface 11A, and the fourth through sixth semiconductor switches Q4 through Q6 are arranged in a row along the longitudinal direction (left-right) on the rear side of the first circuit surface 11A. The first and fourth semiconductor switches Q1 and Q4 are arranged side by side in a lateral direction (front-rear). The second and fifth semiconductor switches Q2 and Q5 are arranged side by side in the lateral direction (front-rear). The third and sixth semiconductor switches Q3 and Q6 are arranged side by side in the lateral direction (front-rear).

The respective packages of the first through sixth semiconductor switches Q1 through Q6 are plate-shaped, and include (i) first ends 46A, 56A, 66A, 76A, 86A, and 96A and (ii) second ends 46B, 56B, 66B, 76B, 86B, and 96B opposite the respective first ends. The drain terminals 42, 52, 62, 72, 82, and 92 of the first through sixth semiconductor switches Q1 through Q6 protrude from the respective first ends 46A, 56A, 66A, 76A, 86A, and 96A. The gate terminals 41, 51, 61, 71, 81, and 91 of the first through sixth semiconductor switches Q1 through Q6 protrude from the respective second ends 46B, 56B, 66B, 76B, 86B, and 96B. The source terminals 43, 53, 63, 73, 83, and 93 of the first through sixth semiconductor switches Q1 through Q6 protrude from the respective second ends 46B, 56B, 66B, 76B, 86B, and 96B.

The first semiconductor switch Q1 includes (i) a first metal surface 46 and (ii) a first mount surface 48 opposite the first metal surface 46. The second semiconductor switch Q2 includes (i) a second metal surface 56 and (ii) a second mount surface 58 opposite the second metal surface 56. The third semiconductor switch Q3 includes (i) a third metal surface 66 and (ii) a third mount surface 68 opposite the third metal surface 66. The fourth semiconductor switch Q4 includes (i) a fourth metal surface 76 and (ii) a fourth mount surface 78 (not shown in FIGS. 3 and 4) opposite the fourth metal surface 76. The fifth semiconductor switch Q5 includes (i) a fifth metal surface 86 and (ii) a fifth mount surface 88 (not shown in FIGS. 3 and 4) opposite the fifth metal surface 86. The sixth semiconductor switch Q6 includes (i) a sixth metal surface 96 and (ii) a sixth mount surface 98 (not shown in FIGS. 3 and 4) opposite the sixth metal surface 96.

The first through sixth metal surfaces 46, 56, 66, 76, 86, and 96 include respective metal plates (metal pads) joined to respective surfaces of the packages of the first through sixth semiconductor switches Q1 through Q6. The metal plates contain aluminum, copper, silver, or gold, or are made of aluminum, copper, silver, or gold. The first through sixth semiconductor switches Q1 through Q6 are mounted on the first circuit surface 11A such that the first through sixth mount surfaces 48, 58, 68, 78, 88, and 98 face the first circuit surface 11A. The first through sixth mount surfaces 48, 58, 68, 78, 88, and 98 are soldered to the first circuit surface 11A.

The first through sixth semiconductor switches Q1 through Q6 are arranged on the first circuit surface 11A such that the first ends 46A, 56A, 66A, 76A, 86A, and 96A are on the front side and such that the second ends 46B, 56B, 66B, 76B, 86B, and 96B are on the rear side. Thus, the source terminal 43 of the first semiconductor switch Q1 faces the drain terminal 72 of the fourth semiconductor switch Q4. The source terminal 53 of the second semiconductor switch Q2 faces the drain terminal 82 of the fifth semiconductor switch Q5. The source terminal 63 of the third semiconductor switch Q3 faces the drain terminal 92 of the sixth semiconductor switch Q6. The source terminals 43, 53, and 63 are electrically coupled to the drain terminals 72, 82, and 92, respectively, through not-shown printed wirings (or conductive traces, or conductive tracks) and/or not-shown vias on the first circuit surface 11A. The printed wirings are formed from metal foils having relatively high electrical conductivity. More specifically, the metal foils contain copper, silver, or gold. The vias are filled or plated with metal. The metal contains copper, silver, or gold.

The first thermistor 27 is disposed, on the first circuit surface 11A, between the first semiconductor switch Q1 and the second semiconductor switch Q2. The second thermistor 29 is disposed, on the first circuit surface 11A, between the fourth semiconductor switch Q4 and the fifth semiconductor switch Q5. In the present example, the first through sixth semiconductor switches Q1 through Q6 each have a first height H1. The first and second thermistors 27 and 29 each have a second height H2. The first height H1 and the second height H2 each correspond to a length in a vertical direction (up-down), and the second height H2 is greater than the first height H1.

The U-phase terminal 45 is disposed, on the first circuit surface 11A, between the first semiconductor switch Q1 and the fourth semiconductor switch Q4. The source terminal 43 of the first semiconductor switch Q1, the drain terminal 72 of the fourth semiconductor switch Q4, and the U-phase terminal 45 are electrically coupled to each other. The drain terminal 42 of the first semiconductor switch Q1 is electrically coupled to the power line Lp through a not-shown printed wiring and/or a not-shown via on the first circuit surface 11A. The source terminal 73 of the fourth semiconductor switch Q4 is electrically coupled to the ground line Ln through a not shown printed wiring and/or a not-shown via on the first circuit surface 11A.

The V-phase terminal 55 is disposed, on the first circuit surface 11A, between the second semiconductor switch Q2 and the fifth semiconductor switch Q5. The source terminal 53 of the second semiconductor switch Q2, the drain terminal 82 of the fifth semiconductor switch Q5, and the V-phase terminal 55 are electrically coupled to each other. The drain terminal 52 of the second semiconductor switch Q2 is electrically coupled to the power line Lp through a not-shown printed wiring and/or a not-shown via on the first circuit surface 11A. The source terminal 83 of the fifth semiconductor switch Q5 is electrically coupled to the ground line Ln through a not-shown printed wiring and/or a not-shown via on the first circuit surface 11A.

The W-phase terminal 65 is disposed, on the first circuit surface 11A, between the third semiconductor switch Q3 and the sixth semiconductor switch Q6. The source terminal 63 of the third semiconductor switch Q3, the drain terminal 92 of the sixth semiconductor switch Q6, and the W-phase terminal 65 are electrically coupled to each other. The drain terminal 62 of the third semiconductor switch Q3 is electrically coupled to the power line Lp through a not-shown printed wiring and/or a not-shown via on the first circuit surface 11A. The source terminal 93 of the sixth semiconductor switch Q6 is electrically coupled to the ground line Ln through a not-shown printed wiring and/or a not-shown via on the first circuit surface 11A.

Each elastic member 35 is conductive. Specifically, the elastic member 35 is a formed spring made of metal, such as copper or aluminum. More specifically, the elastic member 35 has a vertical cross-section that is Z-shaped, but the vertical cross-sectional shape is not limited to Z-shape. In another embodiment, the elastic member 35 may be a coil spring made of metal. Alternatively, the elastic member 35 may be sponge with its surface coated with a conductive material.

The respective elastic members 35 are disposed on the first circuit surface 11A to the right of the first semiconductor switch Q1, to the left of the third semiconductor switch Q3, to the right of the fourth semiconductor switch Q4, and to the left of the sixth semiconductor switch Q6. Each elastic member 35 includes (i) a first member surface 35A and (ii) a second member surface 35B opposite the first member surface 35A. The first member surface 35A is joined to the first circuit surface 11A with solder or the like.

Each metal plate 100 is a plate member having a rectangular shape. These metal plates 100 are arranged above the first circuit surface 11A such that their longitudinal directions are along the longitudinal direction (left-right) of the circuit board 11. One of the metal plates 100 is arranged to cover upper surfaces of the three high-side switches (i.e., the first through third semiconductor switches Q1 through Q3). The upper surfaces of the three high-side switches include the first through third metal surfaces 46, 56, and 66. The other of the metal plates 100 is arranged to cover upper surfaces of the three low-side switches (i.e., the fourth through sixth semiconductor switches Q4 through Q6). The upper surfaces of the three low-side switches include the fourth through sixth metal surfaces 76, 86, and 96. The metal plates 100 do not cover any of the four elastic members 35. The metal plates 100 are members for enhancing the dissipation of heat generated in the first through sixth semiconductor switches Q1 through Q6. Although FIG. 4 illustrates a longitudinal cross section through the high-side switches, the structure around the low-side switches is similar to that around the high-side switches. Thus, the structure around the high-side switches will be described below, and a description of the structure around the low-side switches is omitted.

The metal plate 100 includes (i) a first plate surface 100A and (ii) a second plate surface 100B opposite the first plate surface 100A. The first plate surface 100A is joined to the first through third metal surfaces 46, 56, and 66 via solder. In another embodiment, the first plate surface 100A may be joined to the first through third metal surfaces 46, 56, and 66 via an adhesive with relatively high thermal conductivity. Examples of such an adhesive include silicon and epoxy resin.

The metal plate 100 includes a metal base 140, an insulating layer 130, first through third metal foils 111 through 113, a right insulating portion 121, first and second insulating portions 122 and 123, and a left insulating portion 124. The metal base 140 is a metal plate made of aluminum. That is, the metal base 140 is a metal plate with relatively high thermal conductivity and excellent heat dissipation. In another embodiment, the metal base 140 may be a metal plate made of another metal, such as copper. The metal base 140 may be any metal plate having excellent heat dissipation. An upper surface of the metal base 140 corresponds to the second plate surface 100B.

The insulating layer 130 is joined to a lower surface of the metal base 140. In detail, an upper surface of the insulating layer 130 is joined to the lower surface of the metal base 140 with an adhesive or the like. The insulating layer 130 contains a material having excellent electrical insulating and heat-dissipating properties, or is made of such a material. Examples of such a material include silicon and epoxy resin.

The first through third metal foils 111 through 113, the right insulating portion 121, the first and second insulating portions 122 and 123, and the left insulating portion 124 are joined to a lower surface of the insulating layer 130. The first through third metal foils 111 through 113, the right insulating portion 121, the first and second insulating portions 122 and 123, and the left insulating portion 124 form the first plate surface 100A. In other words, the first through third metal foils 111 through 113, the right insulating portion 121, the first and second insulating portions 122 and 123, and the left insulating portion 124 are included in the first plate surface 100A.

The first through third metal foils 111 through 113 are square-shaped metal foils (metal patches) and are, specifically, copper foils. The first through third metal foils 111 through 113 have approximately the same size as the first through third metal surfaces 46, 56, and 66, respectively. In another embodiment, the first through third metal foils 111 through 113 may be other metal foils, such as silver foils or gold foils.

The first metal foil 111 is arranged on the first plate surface 100A so as to face the first metal surface 46. The second metal foil 112 is arranged on the first plate surface 100A so as to face the second metal surface 56. The third metal foil 113 is arranged on the first plate surface 100A so as to face the third metal surface 66. That is, the first through third metal foils 111 through 113 are arranged side by side along the longitudinal direction (left-right) of the circuit board 11 at the same intervals as those of the first through third semiconductor switches Q1 through Q3.

The first metal foil 111 is joined to the first metal surface 46 via a solder layer 101. The second metal foil 112 is joined to the second metal surface 56 by a solder layer 102. The third metal foil 113 is joined to the third metal surface 66 via a solder layer 103. However, no electric current flows between the first through third metal foils 111 through 113 and the first through third metal surfaces 46, 56, and 66, respectively. The first through third metal foils 111 through 113 are provided on the first plate surface 100A for soldering the metal plate 100 to the first through third semiconductor switches Q1 through Q3. The first through third metal surfaces 46, 56, and 66 may be difficult to be soldered to the metal plate 100 depending on the kind of metal contained in the metal plate 100. Particularly, when the metal contained in the metal plate 100 is aluminum, it is difficult to achieve soldering. Inclusion of the first through third metal foils 111 through 113 in the first plate surface 100A enables the first through third metal surfaces 46, 56, and 66 to be soldered to the first plate surface 100A.

The solder layers 101 through 103 are each made of an alloy containing lead and/or tin, and have a higher thermal conductivity than resin or other materials. The first through third semiconductor switches Q1 through Q3 are joined to the metal plate 100 via the solder layers 101 through 103 having high thermal conductivity. Thus, a heat dissipation efficiency in heat dissipation paths from the first through third semiconductor switches Q1 through Q3 to the metal plate 100 can be improved compared with a case where the first through third semiconductor switches Q1 through Q3 are joined to the metal plate 100 with resin or another material.

In another embodiment, the first through third semiconductor switches Q1 through Q3 may be joined to the metal plate 100 via a thermal interface material (TIM), and the first through third metal foils 111 through 113 may be excluded from the metal plate 100. Examples of the TIM include thermal grease (or thermal paste), thermal adhesive, thermal sheet, thermal compound, and thermal putty.

The first and second insulating portions 122 and 123, the right insulating portion 121, and the left insulating portion 124 are solder resists (or solder masks) applied to the insulating layer 130. In another embodiment, the first and second insulating portions 122 and 123, the right insulating portion 121, and the left insulating portion 124 may be formed of an insulating material, or may contain an insulating material. Examples of the insulating material include silicon and epoxy resin.

The first insulating portion 122 is disposed between the first metal foil 111 and the second metal foil 112. The second insulating portion 123 is disposed between the second metal foil 112 and the third metal foil 113. The right insulating portion 121 is disposed to the right of the first metal foil 111. The left insulating portion 124 is disposed to the left of the third metal foil 113.

The metal plate 100 includes a plate through-hole 160 passing through the first insulating portion 122 and through the insulating layer 130 and the metal base 140 located above the first insulating portion 122. The plate through-hole 160 is aligned with the first thermistor 27 mounted on the first circuit surface 11A. Since the second height H2 is greater than the first height H1, the first thermistor 27 does not fit in a space between the first circuit surface 11A and the first insulating portion 122. Thus, the plate through-hole 160 is provided in the metal plate 100. The first thermistor 27 is partially accommodated in the plate through-hole 160.

The metal plate 100 has two female threads 150 formed therein. The female threads 150 each include a helical thread ridge. One of the female threads 150 is formed on an inner surface of a corresponding through-hole passing through the right insulating portion 121 and through the insulating layer 130 and the metal base 140 located above the right insulating portion 121. The other of the female threads 150 is formed on an inner surface of a corresponding through-hole passing through the left insulating portion 124 and through the insulating layer 130 and the metal base 140 located above the left insulating portion 124. In the present embodiment, the female threads 150 are each formed on the inner surfaces of the respective through-holes in the metal base 140. In another embodiment, either one of the female threads 150 may be formed on the inner surface of the corresponding through-hole in the metal base 140.

The second plate surface 100B is joined to an adhesive layer 300. One of the heat dissipation members 200 is in contact with the second plate surface 100B indirectly via the adhesive layer 300. The adhesive layer 300 is formed by applying, to the second plate surface 100B, a material having (i) adhesive properties and (ii) a thermal conductivity higher than that of air or by applying, to the second plate surface 100B, a sheet made of such a material. Specifically, the adhesive layer 300 is formed of the TIM, more specifically, of thermal compound. Typically, the second plate surface 100B has fine irregularities. A bottom surface of the heat dissipation member 200 also has fine irregularities. The adhesive layer 300 fills a gap between the second plate surface 100B and the bottom surface of the heat dissipation member 200 to thereby enhance a heat dissipation efficiency in a heat dissipation path from the metal plate 100 to the heat dissipation member 200. In another embodiment, the adhesive layer 300 and the heat dissipation member 200 may be excluded from the drive unit 25. In a case where a sufficient heat dissipation effect can be achieved by the metal plate 100 alone, the heat dissipation member 200 need not be joined to the metal plate 100.

In another embodiment, the adhesive layer 300 may be excluded from the drive unit 25 and the heat dissipation member 200 may be directly joined to the second plate surface 100B. In still another embodiment, the metal plate 100 and the adhesive layer 300 may be excluded from the drive unit 25. The bottom surface of the heat dissipation member 200 may include an insulating layer formed thereon, and three metal foils may be provided on the insulating layer. Then, the three metal foils may be soldered to the first through third metal surfaces 46, 56, and 66 of the first through third semiconductor switches Q1 through Q3.

The heat dissipation member 200 includes a right end part and a left end part, each in contact with the second member surface 35B of a corresponding one of the two elastic members 35. The heat dissipation member 200 is not fixed to the second member surfaces 35B, and is supported by the elastic force of the elastic members 35. Thus, assembly tolerances of the first through third semiconductor switches Q1 through Q3, the metal plate 100, the adhesive layer 300, and the heat dissipation member 200 are absorbed by the elastic members 35.

Since the elastic members 35 are conductive, the elastic members 35 electrically couples the circuit board 11 to the heat dissipation member 200. Thus, static electricity is inhibited from building up on the circuit board 11, thereby inhibiting a local voltage increase on the circuit board 11 caused by the static electricity and ultimately inhibiting damage to the electronic components on the circuit board 11 due to electrostatic discharge.

In another embodiment, the drive unit 25 may include, in place of the two heat dissipation members 200, a single heat dissipation member that covers the upper surfaces of the first through sixth semiconductor switches Q1 through Q6. The single heat dissipation member may be supported by a single elastic member or by three or more elastic members. The single elastic member or each of the three elastic members may have a configuration similar to that of the elastic member 35.

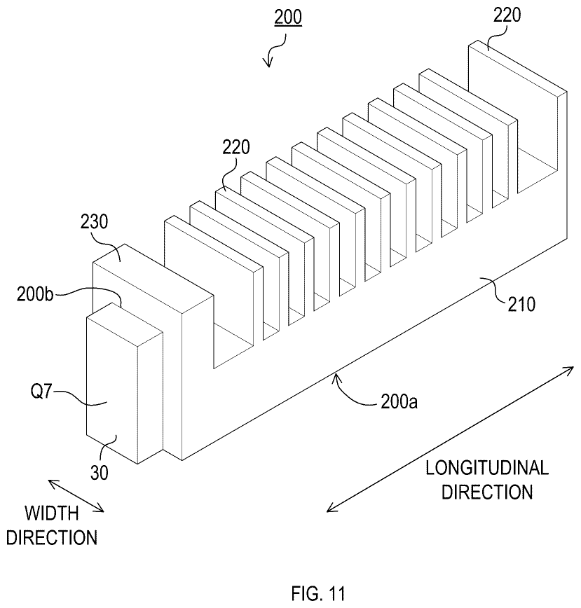

The heat dissipation member 200 is a heat sink made of metal, such as aluminum or copper. As shown in FIGS. 4 and 11, the heat dissipation member 200 includes a base 210, multiple fins 220, and an attachment portion 230. The base 210 is plate-shaped and is joined to the adhesive layer 300 so as to be substantially parallel to the circuit board 11 and the metal plate 100. The base 210 includes two insertion holes 250 passing through the base 210. The insertion holes 250 are each formed to face (or to be aligned with) a corresponding one of the female threads 150. No thread ridges are formed on respective inner surfaces of the insertion holes 250, and the inner surfaces are smooth.

The fins 220 are each plate-shaped. The fins 220 are coupled to the base 210 such that longitudinal directions thereof are along the lateral direction (front-rear) of the circuit board 11. The fins 220 are arranged in parallel with each other in the longitudinal direction (left-right) of the circuit board 11. In another embodiment, the fins 220 may be arranged in parallel with each other on the base 210 in the lateral direction (front-rear) of the circuit board 11 such that the longitudinal directions thereof are along the longitudinal direction (left-right) of the circuit board 11. In another embodiment, the fins 220 may have a shape other than a plate-shape, such as a corrugated shape or a pointed shape.

The attachment portion 230 is plate-shaped and thicker than any of the fins 220. The attachment portion 230 is connected to a right-end part of the base 210 such that its longitudinal direction is along the lateral direction (front-rear) of the circuit board 11. In another embodiment, the attachment portion 230 may be connected to a left-end part of the base 210. Alternatively, in another embodiment, the attachment portion 230 may be connected to a front-end part or a rear-end part of the base 210 such that its longitudinal direction is along the longitudinal direction (left-right) of the circuit board 11.

The heat dissipation member 200 includes a first contact surface 200a on the underside of the base 210. The first contact surface 200a is in contact with the first through third semiconductor switches Q1 through Q3 indirectly via the metal plate 100 and so on.

The heat dissipation member 200 includes, on the right end face of the attachment portion 230, a second contact surface 200b distinct from the first contact surface 200a. The second contact surface 200b extends in a direction intersecting the first contact surface 200a. In the present embodiment, the second contact surface 200b extends perpendicularly to the first contact surface 200a.

Referring again to FIGS. 3 and 4, the second contact surface 200b is in contact with the load switch Q7. The load switch Q7 is of a through-hole mounting type. In other words, the load switch Q7 has a through-hole package. More specifically, the load switch Q7 is of a radial lead type. In general, a semiconductor switch having a through-hole package may have a rated voltage and a rated current greater than those of a semiconductor switch having a surface-mount package. In the present embodiment, in order to ensure high reliability and/or high durability, the load switch Q7 has a rated voltage and a rated current higher than those of any of the first through sixth semiconductor switches Q1 through Q6.

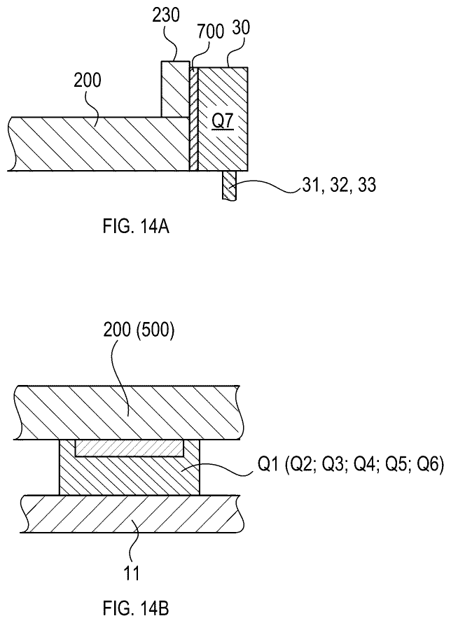

The load switch Q7 includes a body 30. The body 30 has a substantially rectangular parallelepiped shape. The load switch Q7 is screwed to the attachment portion 230 with an outer surface of the body 30 in contact with the second contact surface 200b of the attachment portion 230. In another embodiment, the load switch Q7 may be fixed to the attachment portion 230 by being clamped with a clip or the like with the outer surface of the body 30 in contact with the second contact surface 200b. Alternatively, in another embodiment, as shown in FIG. 14A, the outer surface of the body 30 may be adhered to the second contact surface 200b via an interposed member 700, such as a thin adhesive sheet.

Heat generated in the first through third semiconductor switches Q1 through Q3 is conducted to the heat dissipation member 200 via the metal plate 100, and is then dissipated from the heat dissipation member 200. Heat generated in the load switch Q7 is directly conducted to the heat dissipation member 200, and is then dissipated from the heat dissipation member 200.

The load switch Q7 includes a first lead 31, a second lead 32, and a third lead 33. The first lead 31 is coupled to a gate terminal of the load switch Q7. The second lead 32 is coupled to a drain terminal of the load switch Q7. The third lead 33 is coupled to a source terminal of the load switch Q7. The circuit board 11 includes vias 131 through 133 formed thereon. The vias 131 through 133 pass through the circuit board 11 along its thickness. The first through third leads 31 through 33 extend (or protrude) downward from the body 30. The first through third leads 31 through 33 are (i) inserted into the vias 131 through 133 and (ii) electrically coupled to not-shown printed wirings on the first circuit surface 11A through the vias 131 through 133.

Each male screw 400 includes a threaded portion 410. The threaded portion 410 is a helical thread ridge formed on a cylindrical side surface of the male screw 400. The threaded portion 410 is formed in a location, on the male screw 400 inserted through the corresponding insertion hole 250, that corresponds to the corresponding female thread 150. The male screws 400 are each inserted through the corresponding insertion hole 250, and the corresponding threaded portion 410 is threadedly engaged with the corresponding female thread 150. In response to the threaded portions 410 being threadedly engaged with the female threads 150, the heat dissipation member 200 is firmly fixed to the metal plate 100. Moreover, the degree of adhesion between the heat dissipation member 200 and the adhesive layer 300 and between the adhesive layer 300 and the metal plate 100 increases, thus improving the heat dissipation efficiency from the metal plate 100 to the heat dissipation member 200.

In another embodiment, instead of the female threads 150 being formed in the metal plate 100, the drive unit 25 may include two nuts (or female screws) (i.e., the drive unit 25 may include four nuts in total). The two male screws 400 may each be threadedly engaged with a corresponding one of the two nuts at a corresponding location below the right insulating portion 121 or below the left insulating portion 124.

The first through sixth semiconductor switches Q1 through Q6, the two metal plates 100, and the two heat dissipation members 200 are assembled to the circuit board 11, and then, the drive unit 25 is molded with resin. The drive unit 25 molded with the resin is housed in the housing 2. In another embodiment, after the first through sixth semiconductor switches Q1 through Q6, the two metal plates 100, and the two heat dissipation members 200 are assembled to the circuit board 11, the drive unit 25 may be housed in a casing. The casing is then housed in the housing 2.

### <1-3-2. Modified Example>

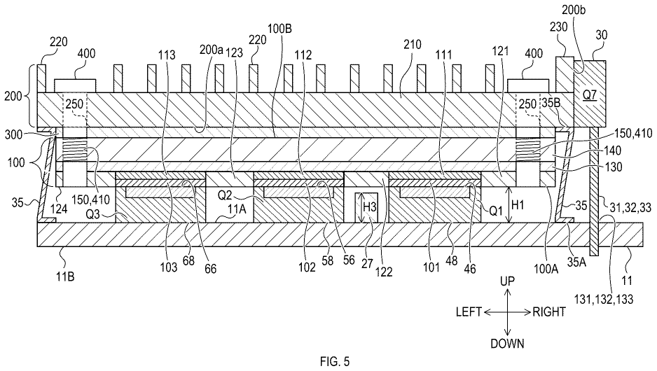

A modified example of the drive unit 25 will be described with reference to FIG. 5. The modified example differs from the above-described examples in that the first thermistor 27 has a third height H3 in place of the second height H2. Moreover, the modified example differs from the above-described examples in that the metal plate 100 does not include the plate through-hole 160. The third height H3 is smaller than the first height H1. Therefore, the first thermistor 27 according to the modified example fits in the space between the first circuit surface 11A and the first insulating portion 122; thus, the plate through-hole 160 is not provided in the metal plate 100 according to the modified example.

### 1-4. Effects

The first embodiment detailed above can achieve the following effects:
(1) In the electric work machine 1, the load switch Q7 having the through-hole package has high reliability and/or high durability compared with the first through sixth semiconductor switches Q1 through Q6 having the surface-mount packages. Accordingly, the load switch Q7 can interrupt the power line Lp with high reliability.

In general, a semiconductor switch having a through-hole package is superior to a semiconductor switch having a surface-mount package in terms of resistance to impact shock, resistance to vibration, and resistance to environmental conditions. Thus, the load switch Q7 can interrupt the power line Lp with high reliability in applications where the electric work machine 1 is prone to impact shock and/or vibration or under severe environments as well. Accordingly, the safety of the electric work machine 1 can be enhanced.
(2) The first through sixth semiconductor switches Q1 through Q6 repeatedly perform switching operations for controlling the motor current, thus generating a large amount of heat. In contrast, the load switch Q7 has a lower switching frequency than the first through sixth semiconductor switches Q1 through Q6 thus allowing its heat generation to be reduced and making failure caused by heat generation less likely to occur. Accordingly, the safety of the electric work machine 1 can be further enhanced.
(3) While the first through sixth semiconductor switches Q1 through Q6 are mounted on the circuit board 11 by surface mounting, the load switch Q7 is mounted on the circuit board 11 by through-hole mounting. More specifically, the body 30 of the load switch Q7 is spaced apart from the circuit board 11. As a result, heat generated in the first through sixth semiconductor switches Q1 through Q6 is less likely to be conducted to the body 30 through the circuit board 11. Accordingly, it is possible to reduce the likelihood that heat generated in the first through sixth semiconductor switches Q1 through Q6 causes thermal runaway or failure in the load switch Q7.
(4) One of the heat dissipation members 200 is (i) in contact with the first through third semiconductor switches Q1 through Q3 indirectly via the metal plate 100 and so on, and (ii) in contact with the load switch Q7 directly. That is, the heat dissipation member 200 is configured to dissipate heat generated in the first through third semiconductor switches Q1 through Q3 and heat generated in the load switch Q7. Accordingly, it is possible to further reduce the likelihood of thermal runaway or failure in the load switch Q7.
(5) One of the heat dissipation member 200 is shared by the first through third semiconductor switches Q1 through Q3 and the load switch Q7, thus eliminating the need to provide a heat dissipation member dedicated to the load switch Q7 in the electric work machine 1. This makes it possible to reduce the number of components of the electric work machine 1, while achieving dissipation of heat from the load switch Q7.
(6) The heat dissipation members 200 each include the second contact surface 200b in addition to the first contact surface 200a. Therefore, one of the heat dissipation members 200 can establish a thermal conduction path for the load switch Q7 separately from thermal conduction paths for the first through third semiconductor switches Q1 through Q3. This enables heat generated in the first through third semiconductor switches Q1 through Q3 and heat generated in the load switch Q7 to be dissipated efficiently.
(7) The second contact surface 200b is not provided on the same plane as the first contact surface 200a, thus inhibiting a portion of each of the heat dissipation members 200 from being too large. This makes it possible to inhibit each of the heat dissipation member 200 from being excessively large in size. As a result, it is possible to suppress an increase in the size of each of the heat dissipation members 200 and also suppress an increase in the size of the electric work machine 1.
(8) The first contact surface 200a extends perpendicularly to the second contact surface 200b. Therefore, one of the heat dissipation members 200 can suppress the positions of the first through third semiconductor switches Q1 through Q3 from overlapping with the position of the load switch Q7. This makes it possible to suppress interference between any one of the first through third semiconductor switches Q1 through Q3 and the load switch Q7 around the heat dissipation member 200.
(9) The first contact surface 200a of one of the heat dissipation members 200 is configured to be in contact with the first through third semiconductor switches Q1 through Q3 on the circuit board 11. In addition, the first contact surface 200a of the other of the heat dissipation members 200 is configured to be in contact with the fourth through sixth semiconductor switches Q4 through Q6 on the circuit board 11. As a result, each of the first through sixth semiconductor switches Q1 through Q6 can easily come into contact with its corresponding heat dissipation member 200.
(10) Each of the heat dissipation members 200 can dissipate heat efficiently by the fins 200. In addition, in each of the heat dissipation members 200, the attachment portion 230 is thicker than any of the fins 220, thus enabling the load switch Q7 to be stably supported.

### 1-5. Correspondence Between Terms

Any one of the first through sixth semiconductor switches Q1 through Q6 corresponds to an example of the first semiconductor switch in Overview of Embodiments. Any one of the rest of the first through sixth semiconductor switches Q1 through Q6 corresponds to an example of the second semiconductor switch in Overview of Embodiments. The load switch Q7 corresponds to an example of the semiconductor load switch in Overview of Embodiments.

### 2. Second Embodiment

### 2-1. Differences From First Embodiment

Since a basic configuration of the second embodiment is similar to that of the first embodiment, differences from the first embodiment will be described below. The reference numerals that are the same as those in the first embodiment indicate the same components, and the preceding descriptions are to be referred to.

In the drive unit 25 of the above-described first embodiment, the first through sixth semiconductor switches Q1 through Q6 are mounted on the first circuit surface 11A. On the other hand, the drive unit 25 according to the second embodiment is different from the drive unit 25 according to the first embodiment in that the low-side switches (i.e., the fourth through sixth semiconductor switches Q4 through Q6) are mounted on the second circuit surface 11B. In other words, in the second embodiment, the electronic components of the drive circuit 21 are mounted on the two surfaces of the circuit board 11. Thus, the circuit board 11 according to the second embodiment is made smaller than the circuit board 11 according to the first embodiment.

In addition, the drive unit 25 of the second embodiment differs from that of the first embodiment (i) in that it includes three metal components 600, first through third printed wirings 511 through 513, and fourth through sixth printed wirings 521 through 523, and (ii) in that it includes one of the heat dissipation members 200 and an additional heat dissipation member 500 in place of the two heat dissipation members 200.

### 2-2. Drive Unit

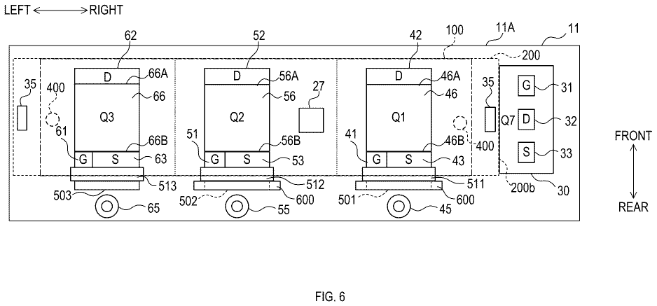

An example of the drive unit 25 according to the second embodiment will be described with reference to FIGS. 6 through 10. As shown in FIG. 6, the first through third semiconductor switches Q1 through Q3 are arranged in a row along the longitudinal direction (left-right) on the first circuit surface 11A. The first through third semiconductor switches Q1 through Q3 are arranged such that the first ends 46A, 56A, and 66A are on the front side and such that the second ends 46B, 56B, and 66B are on the rear side.

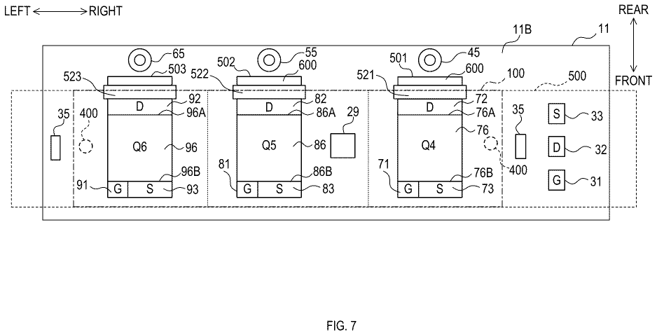

As shown in FIG. 7, the fourth through sixth semiconductor switches Q4 through Q6 are arranged in a row along the longitudinal direction (left-right) on the second circuit surface 11B. The fourth through sixth semiconductor switches Q4 through Q6 are opposite the first through third semiconductor switches Q1 through Q3, respectively, via the circuit board 11. The fourth through sixth semiconductor switches Q4 through Q6 are arranged such that the second ends 76B, 86B, and 96B are on the front side and such that the first ends 76A, 86A, and 96A are on the rear side.

Accordingly, the source terminal 43 of the first semiconductor switch Q1 is opposite the drain terminal 72 of the fourth semiconductor switch Q4 via the circuit board 11. The source terminal 53 of the second semiconductor switch Q2 is opposite the drain terminal 82 of the fifth semiconductor switch Q5 via the circuit board 11. The source terminal 63 of the third semiconductor switch Q3 is opposite the drain terminal 92 of the sixth semiconductor switch Q6 via the circuit board 11.

The circuit board 11 includes first through third board through-holes 501 through 503 passing through the circuit board 11. The first through third board through-holes 501 through 503 are slits extending in the longitudinal direction (left-right). The first through third board through-holes 501 through 503 are disposed in the immediate vicinity of the respective source terminals 43, 53, and 63 and of the respective gate terminals 41, 51, and 61 (e.g., within 10 millimeters from the respective terminals) along the respective second ends 46B, 56B, and 66B of the first through third semiconductor switches Q1 through Q3. Accordingly, the first through third board through-holes 501 through 503 are disposed in the immediate vicinity of the drain terminals 72, 82, and 92, respectively, along the respective first ends 76A, 86A, and 96A of the fourth through sixth semiconductor switches Q4 through Q6.

The length of each of the first through third board through-holes 501 through 503 in the longitudinal direction (left-right) is substantially equal to the width of at least corresponding one of the first through sixth semiconductor switches Q1 through Q6 in the longitudinal direction (left-right). In another embodiment, the respective planar shapes of the first through third board through-holes 501 through 503 may be elliptical, circular, or polygonal.

The metal components 600 are each inserted into a corresponding one of the first through third board through-holes 501 through 503. In FIGS. 6 and 7, for convenience, the first and second board through-holes 501 and 502 have the respective metal components 600 inserted therein and the other metal component 600 is removed from the third board through-hole 503. In practice, all of the first through third board through-holes 501 through 503 are filled with the respective metal components 600.

The metal components 600 contain metal with relatively high electrical conductivity, or are made of such metal. Examples of such metal include copper, silver, gold, and aluminum. The metal components 600 are solid members manufactured in advance. In another embodiment, at least one of the three metal components 600 may be made of conductive paste that is filled into any of the first through third board through-holes 501 through 503 and then hardened or sintered. The conductive paste may be metal paste, more specifically, gold paste, silver paste, copper paste, or aluminum paste. In still another embodiment, at least one of the three metal components 600 may be made of solder that is filled into any of the first through third board through-holes 501 through 503 and then solidified.

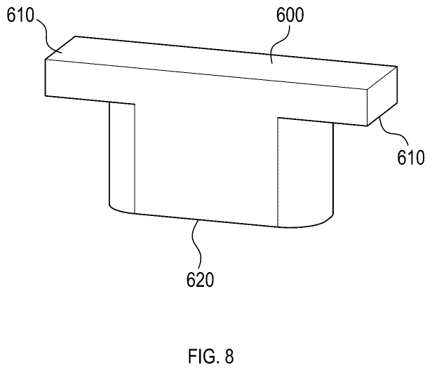

As shown in FIG. 8, the metal components 600 each include a first part 610 and a second part 620. The first part 610 has a substantially rectangular parallelepiped shape. In a horizontal planar view, the size of the first part 610 in its longitudinal direction is larger than that of each of the first through third board through-holes 501 through 503 in the longitudinal direction (left-right) of the circuit board 11. In a horizontal planar view, the size of the first part 610 in its lateral direction is slightly smaller than that of each of the first through third board through-holes 501 through 503 in the lateral direction (front-rear) of the circuit board 11, but may be the same as or larger than that. The second part 620 has a shape similar to a rectangular parallelepiped. The second part 620 is connected to a lower face of the first part 610 such that the longitudinal direction of the second part 620 is aligned with the longitudinal direction of the first part 610. The size of the second part 620 in its longitudinal direction is slightly smaller than that of each of the first through third board through-holes 501 through 503 in the longitudinal direction (left-right) of the circuit board 11. The size of the second part 620 in its lateral direction is slightly smaller than that of each of the first through third board through-holes 501 through 503 in the lateral direction (front-rear) of the circuit board 11. The height of the second part 620 is substantially equal to the thickness of the circuit board 11. The metal components 600 each have a T-shaped vertical cross-section but may have a vertical cross-section of another shape.

The metal components 600 are each inserted into a corresponding one of the first through third board through-holes 501 through 503 from the first circuit surface 11A toward the second circuit surface 11B. The first parts 610 each engage with the first circuit surface 11A, thereby inhibiting the corresponding metal component 600 from coming off from the circuit board 11. The second parts 620 are each accommodated in a corresponding one of the first through third board through-holes 501 through 503.

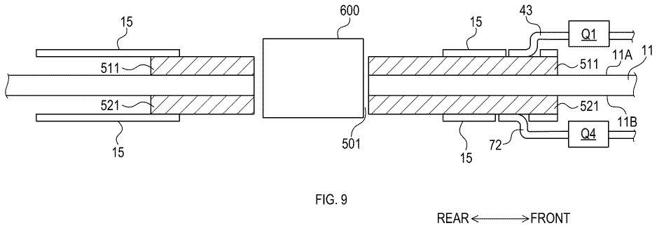

As shown in FIGS. 6 and 9, each of the first through third printed wirings 511 through 513 is disposed between a corresponding one of the source terminals 43, 53, and 63 of the first through third semiconductor switches Q1 through Q3 and a corresponding one of the first through third board through-holes 501 through 503. In addition, each of the first through third printed wirings 511 through 513 is disposed on the rear side of a corresponding one of the first through third board through-holes 501 through 503.

The first through third printed wirings 511 through 513 are electrically coupled to the source terminals 43, 53, and 63, respectively. Specifically, the first through third printed wirings 511 through 513 are soldered to the source terminals 43, 53, and 63, respectively. In addition, the first through third printed wirings 511 through 513 are each electrically coupled to a corresponding one of the metal components 600. Specifically, the first through third printed wirings 511 through 513 are each soldered to the first part 610 of the corresponding metal component 600. The metal components 600 are each electrically coupled to a corresponding one of the U-phase terminal 45, the V-phase terminal 55, and the W-phase terminal 65 via a corresponding one of the first through third printed wirings 511 through 513.

In areas between the source terminal 43 and the corresponding metal component 600, between the source terminal 53 and the corresponding metal component 600, and between the source terminal 63 and the corresponding metal component 600, solder resist 15 is applied onto the first through third printed wirings 511 through 513. In addition, in areas on the rear sides of the three metal components 600, the solder resist 15 is applied onto the first through third printed wirings 511 through 513. The solder resist 15 is not applied below the first through third mount surfaces 48, 58, and 68. Respective lower ends of the gate terminals 41, 51, and 61, the drain terminals 42, 52, and 62, and the source terminals 43, 53, and 63 are located a little above a corresponding one of the first through third mount surfaces 48, 58, and 68. If the solder resist 15 were applied below the first through third mount surfaces 48, 58, and 68, soldering of the gate terminals 41, 51, and 61, the drain terminals 42, 52, and 62, and the source terminals 43, 53, and 63 would be difficult.

As shown in FIGS. 7 and 9, each of the fourth through sixth printed wirings 521 through 523 is disposed between a corresponding one of the drain terminals 72, 82, 92 of the fourth through sixth semiconductor switches Q4 through Q6 and a corresponding one of the first through third board through-holes 501 through 503. In addition, each of the fourth through sixth printed wirings 521 through 523 is disposed on the rear side of a corresponding one of the first through third board through-holes 501 through 503.

The fourth through sixth printed wirings 521 through 523 are electrically coupled to the drain terminals 72, 82, and 92, respectively. Specifically, the fourth through sixth printed wirings 521 through 523 are soldered to the drain terminals 72, 82, and 92, respectively. In addition, the fourth through sixth printed wirings 521, 522, and 523 are each electrically coupled to a corresponding one of the metal components 600. Specifically, the fourth through sixth printed wirings 521 through 523 are each soldered to the second part 620 of the corresponding metal component 600. The metal components 600 are each electrically coupled to a corresponding one of the U-phase terminal 45, the V-phase terminal 55, and the W-phase terminal 65 via a corresponding one of the fourth through sixth printed wirings 521 through 523.

In areas between the drain terminal 72 and the corresponding metal component 600, between the drain terminal 82 and the corresponding metal component 600, and between the drain terminal 92 and the corresponding metal component 600, the solder resist 15 is applied onto the fourth through sixth printed wirings 521 through 523. In addition, in areas on the rear sides of the three metal components 600, the solder resist 15 is applied onto the fourth through sixth printed wirings 521 through 523. The solder resist 15 is not applied below the fourth through sixth mount surfaces 78, 88, and 98.

Each of the source terminals 43, 53, 63 of the first through third semiconductor switches Q1 through Q3 is electrically coupled to a corresponding one of the drain terminals 72, 82, 92 of the fourth through sixth semiconductor switches Q4 through Q6, via a corresponding one of the metal components 600. Thus, the lengths of the printed wirings from the source terminals 43, 53, and 63 to the respective drain terminals 72, 82, and 92 are suppressed to be minimum. This results in reducing the inductive component of the drive circuit 21. Accordingly, the surge voltages associated with the switching operations of the first through sixth semiconductor switches Q1 through Q6 are suppressed, thus allowing the rated voltages of the first through sixth semiconductor switches Q1 through Q6 to be lower. This furthermore enables reduction of heat generated in the first through sixth semiconductor switches Q1 through Q6. Consequently, at least one of the metal plates 100, the heat dissipation members 200 and 500 can be excluded or made smaller in size, and the electronic components on the circuit board 11 can be reduced in size. This in turn enables a reduction in the size and cost of the drive unit 25.

It is also possible to electrically couple the source terminals 43, 53, and 63 to the respective drain terminals 72, 82, and 92 through the printed wirings and the vias without using the metal components 600. However, in the case of coupling these terminals through the printed wirings and the vias, the printed wirings have to be longer, and the inductive component of the printed wirings can be increased. This in turn increases the surge voltages associated with the switching operations of the first through sixth semiconductor switches Q1 through Q6.

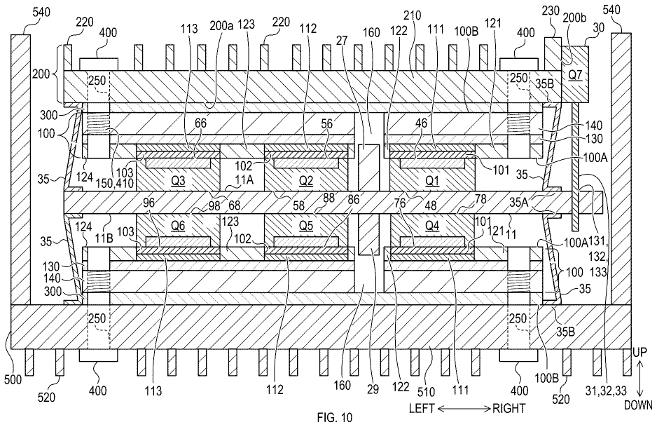

As shown in FIG. 10, similarly to the first embodiment, one of the metal plates 100 and the heat dissipation member 200 are joined onto the high-side switches. On the other hand, the other of the metal plates 100 and the heat dissipation member 500 are joined onto the low-side switches. The heat dissipation member 500 is the same as the heat dissipation member 200 in basic configuration. The heat dissipation member 500 will be described below focusing on the differences from the heat dissipation member 200.

The heat dissipation member 500 includes a base 510, multiple fins 520, and an outer peripheral wall 540. The base 510 is a plate-shaped member greater in length in the longitudinal direction (left-right) of the circuit board 11 than the base 210. The fins 520 have the same shape as the fins 220. The heat dissipation member 500 includes no portion corresponding to the attachment portion 230. The fins 520 are connected to the base 510 such that longitudinal directions thereof are along the lateral direction (front-rear) of the circuit board 11. The fins 520 are arranged in parallel with each other in the longitudinal direction (left-right) of the circuit board 11. In another embodiment, the fins 520 may be arranged in parallel with each other in the lateral direction (front-rear) of the circuit board 11 on the base 510 such that the longitudinal directions thereof are along the longitudinal direction (left-right) of the circuit board 11. In still another embodiment, the fins 520 may have a shape other than a plate-shape, such as a corrugated shape or a pointed shape.

The outer peripheral wall 540 is connected to an upper surface of the base 510. The outer peripheral wall 540 has a height substantially the same as the length from the upper surface of the base 510 to an upper end of the heat dissipation member 200. The outer peripheral wall 540 surrounds the circuit board 11, the two metal plates 100, and the heat dissipation member 200 on the left side, right side, front side, and rear side thereof.

The first through sixth semiconductor switches Q1 through Q6, the two metal plates 100, the heat dissipation members 200 and 500 are assembled to the circuit board 11, and then, resin is injected into the inside of the outer peripheral wall 540, thus molding the drive unit 25 with the resin. The drive unit 25 molded with the resin is housed in the housing 2.

In another embodiment, the outer peripheral wall 540 may be excluded from the heat dissipation member 500. In the case where the outer peripheral wall 540 is excluded, the drive unit 25 is held in a mold and molded with resin. The drive unit 25 molded with the resin is housed in the housing 2. Alternatively, in the case where the outer peripheral wall 540 is excluded, the drive unit 25 may be housed in a casing. The drive unit 25 housed in the casing is housed in the housing 2.

### 2-3. Modified Example

In FIG. 10, the first and second thermistors 27 and 29 each have the second height H2, and the metal plates 100 each include the plate through-hole 160. However, this may be modified as in the modified example of the first embodiment shown in FIG. 5. Specifically, a configuration may be employed in which the first and second thermistors 27 and 29 each have the third height H3 and in which the metal plates 100 each do not include the plate through-hole 160.

### 2-4. Effects

The second embodiment detailed above can achieve effects similar to those of the above-described first embodiment.

### 3. Other Embodiments

Although the embodiments of the present disclosure have been described so far, the present disclosure is not limited to the above-described embodiments and may be implemented in variously modified forms.
(a) In the heat dissipation member 200 according to the above-described embodiments, as shown in FIGS. 4 and 11, the broader surfaces of the fins 220 extend perpendicularly to the longitudinal direction of the heat dissipation member 200. However, the heat dissipation member of the present disclosure is not limited to such a configuration.

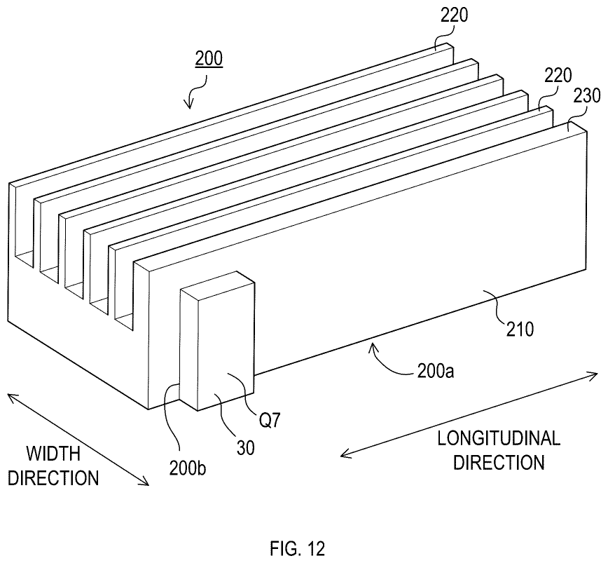

In one further embodiment, as shown in FIG. 12, the broader surfaces of the fins 220 may extend parallel to the longitudinal direction of the heat dissipation member 200. In other words, the broader surfaces of the fins 220 may extend perpendicularly to the lateral direction (i.e., the width direction (see FIG. 12)) of the heat dissipation member 200.

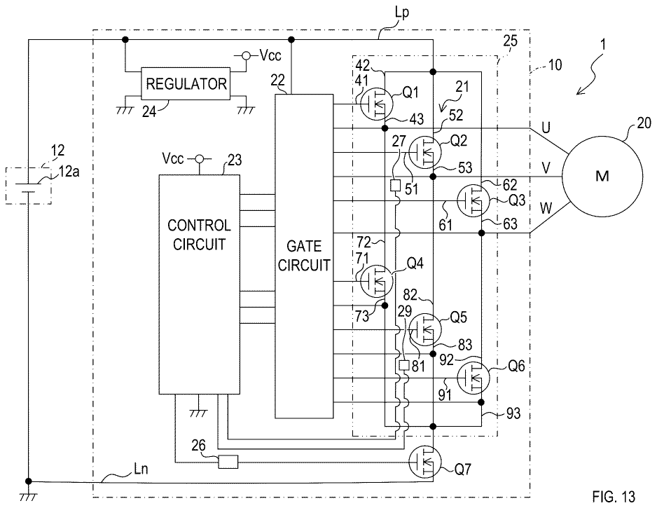

In this case as well, the attachment portion 230 may be formed in a shape of a plate that has a greater thickness than any of the fins 220. The attachment portion 230 may be formed such that the broader surfaces thereof and the broader surfaces of the fins 220 are parallel to each other.
(b) In the above-described embodiments, as shown in FIG. 2, the load switch Q7 is disposed on the power line Lp. However, in one further embodiment, the load switch Q7 may be disposed on the ground line Ln as shown in FIG. 13. In this case, the load switch Q7 can interrupt the ground line Ln.
(c) In the above-described embodiments, each of the first through sixth semiconductor switches Q1 through Q6 is in contact with the heat dissipation member 200 or the heat dissipation member 500 indirectly via the metal plate 100 and the adhesive layer 300. However, in one further embodiment, each of the first through sixth semiconductor switches Q1 through Q6 may be in contact with the heat dissipation member 200 or the heat dissipation member 500 directly (see FIG. 14B). Alternatively, six heat dissipation members may be provided for the respective first through sixth semiconductor switches Q1 through Q6, and the first through sixth semiconductor switches Q1 through Q6 may be in contact with the respective six heat dissipation members directly, or indirectly via respective interposed members.
(d) In one further embodiment, the electric work machine 1 may include, in addition to the load switch Q7, an additional load switch(es). In such a case, the additional load switch(es) may be in contact with the heat dissipation member 200 directly, or indirectly via an interposed member. Alternatively, the additional load switch(es) may be in contact with an additional heat dissipation member(s) directly, or indirectly via an interposed member. Still alternatively, two or more heat dissipation members may be provided for the load switch Q7 and the additional load switch(es), and the load switch Q7 and the additional load switch(es) may be in contact with the respective heat dissipation members directly, or indirectly via respective interposed members.
(e) In the above-described embodiments, a description has been given of the configuration in which the first through sixth semiconductor switches Q1 through Q6 and the load switch Q7 are all mounted on the circuit board 11. However, the present disclosure is not limited to such a configuration. In one further embodiment, the electric work machine 1 may include two or more circuit boards. Specifically, the electric work machine 1 may include: a first circuit board on which the first through sixth semiconductor switches Q1 through Q6 are mounted; and a second circuit board on which the load switch Q7 is mounted. In this case, the first through sixth semiconductor switches Q1 through Q6 and the load switch Q7 may be in contact with the same heat dissipation member directly, or indirectly via an interposed member(s).
(f) In the above-described embodiments, the first through sixth semiconductor switches Q1 through Q6 includes the first through sixth metal surfaces 46, 56, 66, 76, 86, and 96 opposite the circuit board 11. However, the present disclosure is not limited to such a configuration. In a further embodiment, the first through sixth semiconductor switches may (i) include, in addition to or in place of the first through sixth metal surfaces 46, 56, 66, 76, 86, and 96, respective additional metal surfaces facing the circuit board 11 and (ii) be configured to dissipate heat through the respective additional metal surfaces. More specifically, the first through sixth semiconductor switches Q1 through Q6 may each have a DSOP or a TO-Leadless (TOLL) package.
(g) Two or more functions achieved by a single element in the above-described embodiments may be achieved by two or more elements, and a single function achieved by a single element may be achieved by two or more elements. Two or more functions achieved by two or more elements may be achieved by a single element, and a single function achieved by two or more elements may be achieved by a single element. A portion of the configurations in the above-described embodiments may be omitted. At least a portion of the configuration in one of the above-described embodiments may be added to or replace the configuration in another one of the above-described embodiments.

What is claimed is:

1. An electric work machine comprising:
a motor configured to drive a tool;
a drive circuit (i) including a first semiconductor switch having a surface-mount package and (ii) configured to control a motor current by switching operation of the first semiconductor switch, the motor current flowing or to flow between the drive circuit and the motor for driving the motor; and
a semiconductor load switch (i) having a through-hole package and (ii) configured to establish or interrupt conduction between the drive circuit and a power supply for the motor.

2. The electric work machine according to claim 1, further comprising
a circuit board including a via passing through the circuit board along a thickness thereof, wherein:
the semiconductor load switch includes (i) a body and (ii) a lead protruding from the body; and
the semiconductor load switch is mounted on the circuit board with the lead inserted into the via.

3. The electric work machine according to claim 2,
wherein the semiconductor load switch is of a radial lead type.

4. The electric work machine according to claim 3,
wherein the body of the semiconductor load switch is spaced apart from the circuit board.

5. The electric work machine claim 2,
wherein the first semiconductor switch is mounted on the circuit board by surface mounting.

6. The electric work machine according to claim 5,
wherein the drive circuit further includes a second semiconductor switch having a surface-mount package, the second semiconductor switch (i) being distinct from the first semiconductor switch, (ii) being mounted on the circuit board by surface mounting, and (iii) forming, together with the first semiconductor switch, at least a part of an inverter circuit for driving the motor.

7. The electric work machine according to claim 5, further comprising
a heat dissipation member (i) in direct or indirect contact with the first semiconductor switch and with the body of the semiconductor load switch and (ii) configured to dissipate heat generated in the first semiconductor switch and heat generated in the semiconductor load switch.

8. The electric work machine according to claim 7,
wherein the heat dissipation member includes:
a first contact surface in direct or indirect contact with the first semiconductor switch; and
a second contact surface in direct or indirect contact with the body of the semiconductor load switch.

9. The electric work machine according to claim 8, wherein:
the drive circuit further includes a second semiconductor switch having a surface-mount package, the second semiconductor switch (i) being distinct from the first semiconductor switch, (ii) being mounted on the circuit board by surface mounting, and (iii) forming, together with the first semiconductor switch, at least a part of an inverter circuit for driving the motor; and
the first contact surface is in direct or indirect contact with the second semiconductor switch in addition to the first semiconductor switch.

10. The electric work machine according to claim 8,
wherein the first contact surface is distinct from the second contact surface.

11. The electric work machine according to claim 10,
wherein the second contact surface extends in a direction intersecting the first contact surface.

12. The electric work machine according to claim 11,
wherein the second contact surface extends perpendicularly to the first contact surface.

13. The electric work machine according to claim 8,
wherein the heat dissipation member includes (i) two or more fins and (ii) an attachment portion including the second contact surface.

14. The electric work machine according to claim 13, wherein:
the two or more fins are plate-shaped members parallel to each other; and
the attachment portion is a plate-shaped member (i) having a thickness greater than that of any of the two or more fins and (ii) parallel to the two or more fins.

15. The electric work machine according to claim 5, wherein:
the drive circuit further includes a second semiconductor switch having a surface-mount package, the second semiconductor switch (i) being distinct from the first semiconductor switch, (ii) being mounted on the circuit board by surface mounting, and (iii) forming, together with the first semiconductor switch, at least a part of an inverter circuit for driving the motor; and
the electric work machine further includes a heat dissipation member (i) in direct or indirect contact with the first semiconductor switch, with the second semiconductor switch, and with the body of the semiconductor load switch and (ii) configured to dissipate heat generated in the first semiconductor switch, heat generated in the second semiconductor switch, and heat generated in the semiconductor load switch.

16. The electric work machine according to claim 1,
wherein the motor is a brushless DC motor.

17. The electric work machine according to claim 1, further comprising:
a power line configured to deliver the motor current from a positive electrode of the power supply to the drive circuit; and/or
a ground line configured to deliver the motor current from the drive circuit to a negative electrode of the power supply,
wherein the semiconductor load switch is on the power line or on the ground line.

18. A method for constructing an electrical system in an electric work machine, the method comprising:
providing, to a drive circuit of the electric work machine, a semiconductor switch having a surface-mount package, the drive circuit being configured to control a motor current flowing or to flow through a motor of the electric work machine by switching operation of the semiconductor switch; and
coupling the drive circuit to a power supply for the motor via a semiconductor load switch having a through-hole package, the semiconductor load switch being configured to establish or interrupt conduction between the drive circuit and the power supply.
